(19) United States
(12) Patent Application Publication
(10) Pub. No.: US 2026/0075749 A1
(43) Pub. Date: Mar. 12, 2026

(54) NOTEBOOK COMPUTER WITH THREE INLINE REAR EXHAUSTING AIR MOVERS

(71) Applicant: Dell Products L.P., Round Rock, TX (US)

(72) Inventors: Qinghong HE, Austin, TX (US); Ihab SAAD, Austin, TX (US); Jay M. ZILL, Round Rock, TX (US)

(73) Assignee: Dell Products L.P., Round Rock, TX (US)

(21) Appl. No.: 18/883,197

(22) Filed: Sep. 12, 2024

(51) Int. Cl. H05K 7/20; G06F 1/16; G06F 1/20

(52) U.S. Cl. CPC H05K 7/20172; G06F 1/1662; G06F 1/203; G06F 1/206; H05K 7/20154

(57) ABSTRACT

An information handling system may include a display assembly and a keyboard assembly rotationally coupled to the display assembly via a hinge at a rear of the keyboard assembly, the keyboard assembly comprising a housing, an information handling resource housed within the housing, heat-rejecting media housed within the housing and thermally coupled to the information handling resource, wherein a portion of the heat-rejecting media is located at the rear of the keyboard assembly, and three air movers housed within the housing, wherein the heat-rejecting media and the three air movers are arranged such that airflow exhausting from the three air movers flows proximate to surfaces of the portion of the heat-rejecting media located at the rear of the keyboard assembly, and such that the airflow exhausts from the rear of the keyboard assembly.

### TECHNICAL FIELD

The present disclosure relates in general to information handling systems, and more particularly to cooling of information handling system components using one or more air movers, including an air mover shaped to account for lack of air vents proximate to the air mover.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

Airflow is often critical to cooling a notebook computer (e.g., laptop). Traditionally, high-power notebooks typically include only two rear-exhausting air movers. Some information handling systems include more than two air movers, but such additional air movers are often buried deep inside the information handling system or exhaust to the left or right side of the notebook computer. Air movers within an information handling system away from the exhaust may be used to cool lower power components such as memory. Air movers may be located on the left or right sides of the information handling system housing, but placement of air movers on the sides have disadvantages.

For example, one disadvantage is that such side-exhausting air movers occupy the main space for input/output ports that are typically on the left or right sides. As another example, such side-exhausting air movers may blow hot air to regions in which users may place their hands, potentially causing user discomfort.

### SUMMARY

In accordance with the teachings of the present disclosure, the disadvantages and problems associated with traditional approaches to cooling information handling system components may be substantially reduced or eliminated.

In accordance with embodiments of the present disclosure, an information handling system may include a display assembly and a keyboard assembly rotationally coupled to the display assembly via a hinge at a rear of the keyboard assembly, the keyboard assembly comprising a housing, an information handling resource housed within the housing, heat-rejecting media housed within the housing and thermally coupled to the information handling resource, wherein a portion of the heat-rejecting media is located at the rear of the keyboard assembly, and three air movers housed within the housing, wherein the heat-rejecting media and the three air movers are arranged such that airflow exhausting from the three air movers flows proximate to surfaces of the portion of the heat-rejecting media located at the rear of the keyboard assembly, and such that the airflow exhausts from the rear of the keyboard assembly.

In accordance with these and other embodiments of the present disclosure, a method may include thermally coupling heat-rejecting media to an information handling resource within a housing of a keyboard assembly of an information handling resource, wherein the keyboard assembly is configured to rotationally couple to a display assembly via a hinge at a rear of the keyboard assembly, and arranging the heat-rejecting media and three air movers within the housing such that a portion of the heat-rejecting media is located at the rear of the keyboard assembly and such that airflow exhausting from the three air movers flows proximate to surfaces of the portion of the heat-rejecting media located at the rear of the keyboard assembly, and such that the airflow exhausts from the rear of the keyboard assembly. Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of selected components of an example information handling system, in accordance with embodiments of the present disclosure;

FIG. 2 illustrates selected components of an example notebook, in accordance with embodiments of the present disclosure;

FIG. 3 illustrates an isometric perspective view of a bottom of a keyboard assembly depicting selected components of the notebook depicted in FIG. 2, in accordance with embodiments of the present disclosure; and

FIG. 4 illustrates an isometric perspective view of a bottom of another keyboard assembly depicting selected components of the notebook depicted in FIG. 2, in accordance with embodiments of the present disclosure.

### DETAILED DESCRIPTION

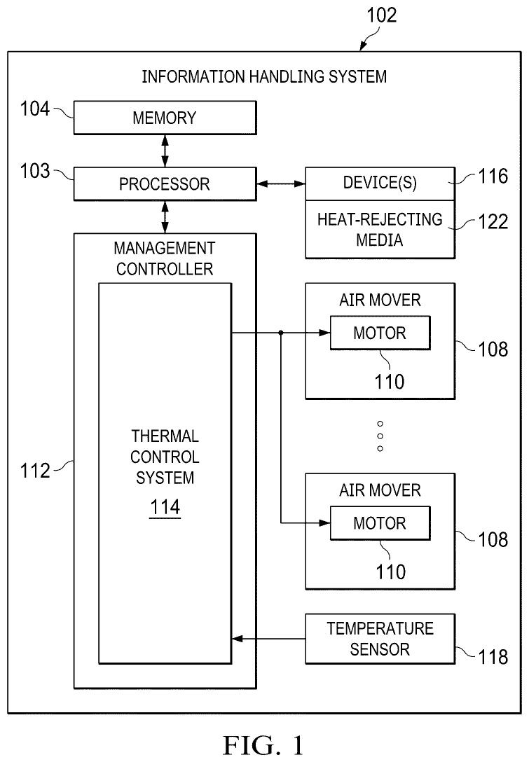

Preferred embodiments and their advantages are best understood by reference to FIGS. 1 through 4, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of selected components of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may comprise a processor 103, a memory 104 communicatively coupled to processor 103, a plurality of air movers 108, a management controller 112, one or more devices 116 communicatively coupled to processor 103, a temperature sensor 118, and heat-rejecting media 122 thermally coupled to device(s) 116.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

An air mover 108 may include any mechanical or electro-mechanical system, apparatus, or device operable to move air and/or other gases in order to cool information handling resources of information handling system 102. In some embodiments, an air mover 108 may comprise a fan (e.g., a rotating arrangement of vanes or blades which act on the air). In other embodiments, an air mover 108 may comprise a blower (e.g., a centrifugal fan that employs rotating impellers to accelerate air received at its intake and change the direction of the airflow). In these and other embodiments, rotating and other moving components of an air mover 108 may be driven by a motor 110. The rotational speed of motor 110 may be controlled by an air mover control signal (e.g., a pulse-width modulation signal) communicated from thermal control system 114 of management controller 112. In operation, an air mover 108 may cool information handling resources of information handling system 102 by drawing cool air into an enclosure housing the information handling resources from outside the chassis, expelling warm air from inside the enclosure to the outside of such enclosure, and/or moving air across one or more heat sinks (not explicitly shown) internal to the enclosure to cool one or more information handling resources. As described in greater detail below, information handling system 102 may be implemented as a notebook computer having three air movers 108 arranged to exhaust from a rear of information handling system 102.

Management controller 112 may comprise any system, device, or apparatus configured to facilitate management and/or control of information handling system 102 and/or one or more of its component information handling resources. Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include a thermal control system 114. Thermal control system 114 may include any system, device, or apparatus configured to receive one or more signals indicative of one or more temperatures within information handling system 102 (e.g., one or more signals from one or more temperature sensors 118) and based on such one or more signals, calculate an air mover driving signal (e.g., a pulse-width modulation signal) to maintain an appropriate level of cooling, increase cooling, or decrease cooling, as appropriate, and communicate such air mover driving signal to air movers 108. Thermal control for air movers 108 by thermal control system 114 may be performed in any suitable manner, for example, as described in U.S. Pat. No. 10,146,190 entitled “Systems and Methods for Providing Controller Response Stability in a Closed-Loop System.”

In addition, thermal control system 114 may also be configured to maintain acoustic limits and/or maintain acoustic preferences for sound generated by air movers 108, for example, as described in U.S. patent application Ser. No. 16/852,118, filed Apr. 17, 2020, and entitled “Systems and Methods for Acoustic Limits of Thermal Control System in an Information Handling System,” which is incorporated by reference herein in its entirety.

In some embodiments, thermal control system 114 may include a program of instructions (e.g., software, firmware) configured to, when executed by a processor or controller integral to management controller 112, carry out the functionality of thermal control system 114.

A device 116 may comprise any component information handling system of information handling system 102, including without limitation processors, buses, memories, I/O devices and/or interfaces, storage resources, network interfaces, motherboards, integrated circuit packages; electro-mechanical devices, displays, and power supplies.

Temperature sensor 118 may comprise any system, device, or apparatus (e.g., a thermometer, thermistor, etc.) configured to communicate a signal to thermal control system 114 indicative of a temperature within information handling system 102.

Heat-rejecting media 122 may include any system, device, or apparatus configured to transfer heat from an information handling resource (e.g., device(s) 116, as shown in FIG. 1), thus reducing a temperature of the information handling resource. For example, heat-rejecting media 122 may include one or more solids thermally coupled to the information handling resource (e.g., heat pipe, heat spreader, heatsink, vapor chamber, finstack, etc.) such that heat generated by the information handling resource is transferred from the information handling resource. Further, heat-rejecting media 122 may be arranged to be located within the airflow path of airflow generated by air movers 108, such that heat transferred to heat-rejecting media 122 from device 116 may further be transferred to such airflow. Although, for purposes of clarity and exposition, heat-rejecting media 122 is shown as being thermally coupled to device(s) 116, it is understood that heat-rejecting media 122 may also be thermally coupled to other information handling resources (e.g., processor 103 and/or memory 104) of information handling system 102 in addition to or in lieu of being thermally coupled to device 116.

In addition to processor 103, memory 104, air mover 108, management controller 112, device(s) 116, temperature sensor 118, and heat-rejecting media 122, information handling system 102 may include one or more other information handling resources. In addition, for the sake of clarity and exposition of the present disclosure, FIG. 1 depicts two air movers 108 and one temperature sensor 118. In embodiments of the present disclosure, information handling system 102 may include any number of air movers 108 and temperature sensors 118.

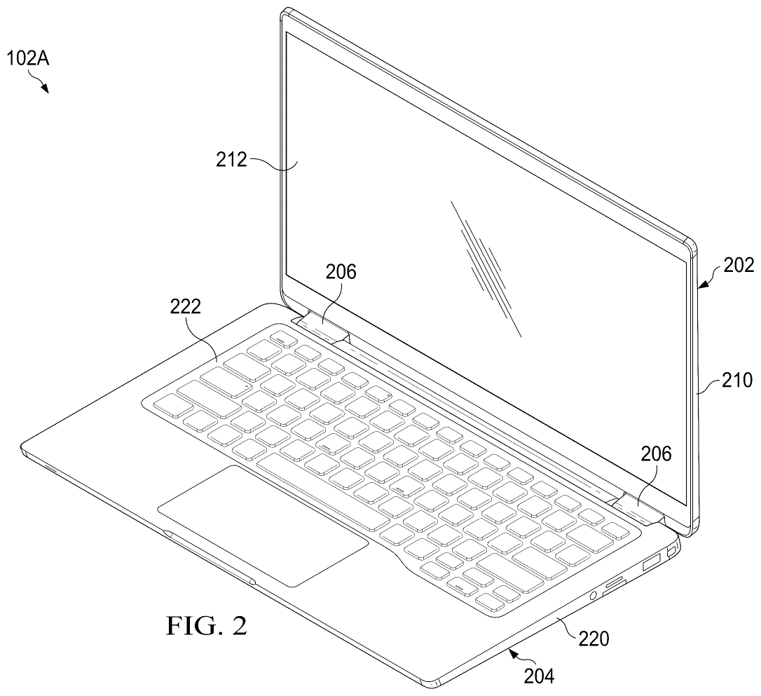

FIG. 2 illustrates selected components of an example notebook 102A, in accordance with embodiments of the present disclosure. Notebook 102A may implement information handling system 102. As shown in FIG. 2, notebook 102A may include a display assembly 202 and a keyboard assembly 204 rotatably coupled to one another via one or more hinges 206. Display assembly 202 may comprise a housing 210 that may house components of notebook 102A including a display device 212 (e.g., liquid-crystal display) for outputting alphanumeric and/or graphical output. Keyboard assembly 204 may comprise a housing 220 that may house components of notebook 102A including a keyboard 222 for inputting information to notebook 102A. Keyboard assembly 204 may also include other components of information handling system 102 (e.g., processor 103, memory 104, management controller 112, device(s) 116, air movers 108, temperature sensor 118, heat-rejecting media 122, etc.) not explicitly depicted in FIG. 2.

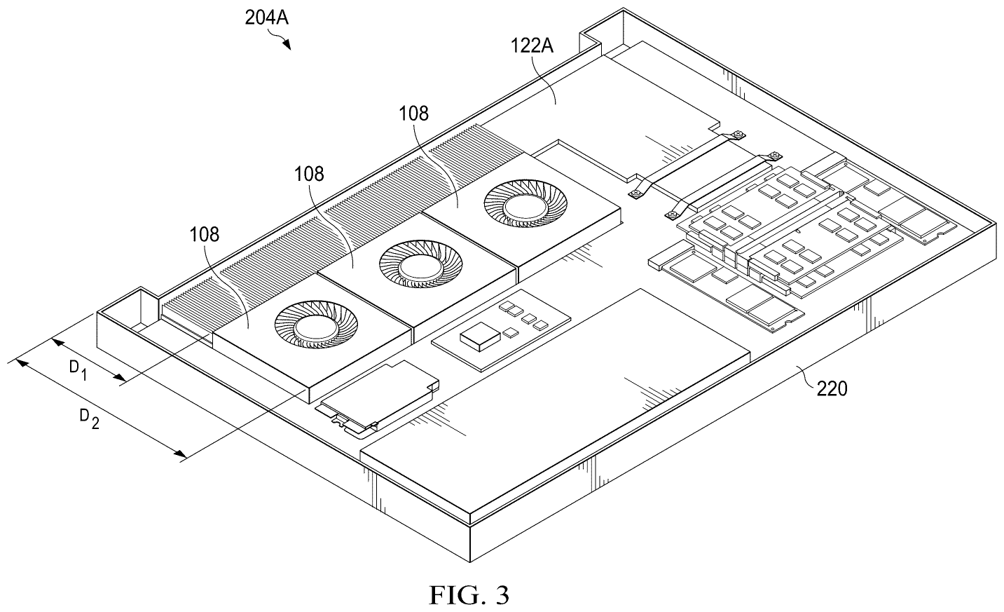

FIG. 3 illustrates an isometric perspective view of a bottom of a keyboard assembly 204A depicting selected components of notebook 102A depicted in FIG. 2, in accordance with embodiments of the present disclosure. In FIG. 3, for purposes of clarity and exposition, a bottom cover (e.g., a “D-cover”) of housing 220 of keyboard assembly 204A is removed to allow FIG. 3 to depict selected components internal to housing 220. Keyboard assembly 204A shown in FIG. 3 may be used to implement keyboard assembly 204 of FIG. 2.

As shown in FIG. 3, keyboard assembly 204A may include (in addition to some of the components depicted in FIG. 1) heat-rejecting media 122A and three air movers 108. Heat-rejecting media 122A may implement heat-rejecting media 122 depicted in FIG. 1. Although FIG. 3 depicts heat-rejecting media 122A as a heat spreader coupled to a fin stack of a plurality of fins, it is understood that any other type of heat-rejecting media (e.g., heat pipes, vapor chambers, etc.) may be used.

Air movers 108 and heat-rejecting media 122A may be arranged such that at least a portion of heat-rejecting media 122A (e.g., a fin stack) is located within airflow exhausted from exhausts of air movers 108. Furthermore, air movers 108 and heat-rejecting media 122A may be arranged such that air movers 108 are located side-by-side and may also be “inline” with each other, such that a depth of air movers 108 from the rear of keyboard assembly 204A, wherein the “rear” is defined as the edge of keyboard assembly 204A at which keyboard assembly 204A couples to display assembly 202, is equal. In other words, the back edges from which air exhausts from air movers 108 may align at a common depth D1 from the rear of keyboard assembly 204A, the front edges opposite the back edges of air movers 108 may align at a common depth D2 from the rear of keyboard assembly 204A, or both.

In operation, heat-rejecting media 122A may be thermally coupled to processor 103 and/or one or more other devices 116 (not showed in FIG. 3 as such components may be obscured from view by heat-rejecting media 122A). Heat generated by such components may be transferred to heat-rejecting media 122A, which in turn may transfer such heat to airflow exhausting from air movers 108 and flowing proximate to surfaces of heat-rejecting media 122A. After flowing proximate to portions of heat-rejecting media 122A, such warmed airflow may exhaust through the rear of keyboard assembly 204A, thus cooling the components to which heat-rejecting media 122A is coupled.

Advantageously, the presence of three rear-exhausting air movers 108 may provide more cooling than existing approaches, such as those described in the Background section, while leaving sides of housing 220 free of hot exhausting air and leaving space for input/output ports along the sides.

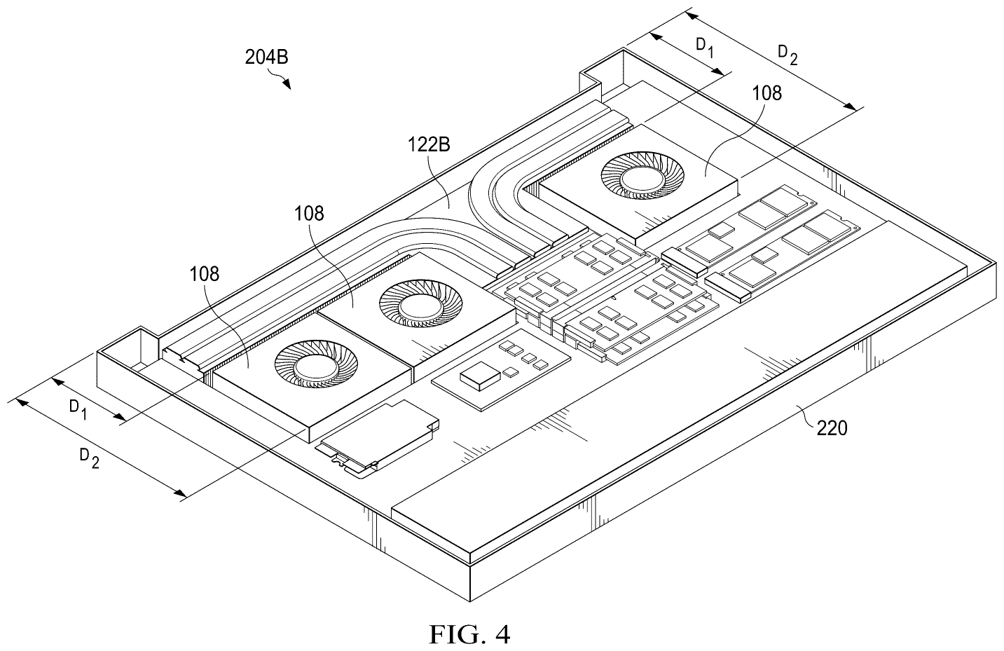

FIG. 4 illustrates an isometric perspective view of a bottom of another keyboard assembly 204B depicting selected components of the notebook depicted in FIG. 2, in accordance with embodiments of the present disclosure. In FIG. 4, for purposes of clarity and exposition, a bottom cover (e.g., a “D-cover”) of housing 220 of keyboard assembly 204B is removed to allow FIG. 4 to depict selected components internal to housing 220. Keyboard assembly 204B shown in FIG. 4 may be used to implement keyboard assembly 204 of FIG. 2.

Keyboard assembly 204B may be similar in many respects to keyboard assembly 204A, and thus only certain differences between keyboard assembly 204A and keyboard assembly 204B may be described below. For example, as shown in FIG. 4, keyboard assembly 204B may include heat-rejecting media 122B in lieu of heat-rejecting media 122A. While heat-rejecting media 122B may have identical or similar functionality to that of heat-rejecting media 122A, heat-rejecting media 122B may be configured (e.g., sized and shaped) differently from heat-rejecting media 122A in order to accommodate separating at least one air mover 108 from other air movers 108 as compared to FIG. 3, such that of the three air movers 108, two of such air movers 108 have a portion of heat-rejecting media 122B between such two air movers 108. Although FIG. 4 depicts heat-rejecting media 122B as a heat spreader coupled to a plurality of heat pipes, it is understood that any other type of heat-rejecting media (e.g., heat spreaders, vapor chambers, fin stacks, etc.) may be used.

While air movers 108 may not be arranged side-by-side-by-side as shown in FIG. 3, air movers 108 of keyboard assembly 204B may be located “inline” with each other, such that a depth of air movers 108 from the rear of keyboard assembly 204B, wherein the “rear” is defined as the edge of keyboard assembly 204B at which keyboard assembly 204B couples to display assembly 202, is equal. In other words, the back edges from which air exhausts from air movers 108 may align at a common depth D1 from the rear of keyboard assembly 204B, the front edges opposite the back edges of air movers 108 may align at a common depth D2 from the rear of keyboard assembly 204B, or both.

While the terms “top,” “bottom,” “front,” “back,” and “side” are used for purposes of exposition and clarity, such terms are not intended to limit any of the components disclosed herein to a particular orientation or configuration.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S. C. § 112(f) unless the words “means for” or “step for” are explicitly used in the particular claim.

What is claimed is:

1. An information handling system comprising:
a display assembly; and
a keyboard assembly rotationally coupled to the display assembly via a hinge at a rear of the keyboard assembly, the keyboard assembly comprising:
a housing;
an information handling resource housed within the housing;
heat-rejecting media housed within the housing and thermally coupled to the information handling resource, wherein a portion of the heat-rejecting media is located at the rear of the keyboard assembly; and
three air movers housed within the housing;
wherein the heat-rejecting media and the three air movers are arranged such that airflow exhausting from the three air movers flows proximate to surfaces of the portion of the heat-rejecting media located at the rear of the keyboard assembly, and such that the airflow exhausts from the rear of the keyboard assembly.

2. The information handling system of claim 1, wherein the three air movers are located side-by-side-by-side relative to one another.

3. The information handling system of claim 1, wherein a second portion of the heat-rejecting media is located between two of the three air movers.

4. The information handling system of claim 1, wherein respective back edges at the respective exhausts of each of the three air movers are located a common depth from the rear of the keyboard assembly.

5. The information handling system of claim 1, wherein respective front edges opposite of the respective exhausts of each of the three air movers are located a common depth from the rear of the keyboard assembly.

6. A method comprising:
thermally coupling heat-rejecting media to an information handling resource within a housing of a keyboard assembly of an information handling resource, wherein the keyboard assembly is configured to rotationally couple to a display assembly via a hinge at a rear of the keyboard assembly; and
arranging the heat-rejecting media and three air movers within the housing such that a portion of the heat-rejecting media is located at the rear of the keyboard assembly and such that airflow exhausting from the three air movers flows proximate to surfaces of the portion of the heat-rejecting media located at the rear of the keyboard assembly, and such that the airflow exhausts from the rear of the keyboard assembly.

7. The method of claim 6, further comprising locating the three air movers side-by-side-by-side relative to one another.

8. The method of claim 6, further comprising locating a second portion of the heat-rejecting media between two of the three air movers.

9. The method of claim 6, further comprising locating respective back edges at the respective exhausts of each of the three air movers at a common depth from the rear of the keyboard assembly.

10. The method of claim 6, further comprising locating respective front edges opposite of the respective exhausts of each of the three air movers at a common depth from the rear of the keyboard assembly.
